(19) United States
(12) Patent Application Publication
(10) Pub. No.: US 2016/0072004 A1
(43) Pub. Date: Mar. 10, 2016

(54) SEMICONDUCTOR LIGHT EMITTING DEVICE

(71) Applicant: SAMSUNG ELECTRONICS CO., LTD., Suwon-si (KR)

(72) Inventors: Sang Yeob SONG, Suwon-si (KR); Ju Heon YOON, Seoul (KR); Gi Bum KIM, Yongin-si (KR); Hyun Young KIM, Yongin-si (KR); Jong Hoon HA, Suwon-si (KR)

(21) Appl. No.: 14/714,117

(22) Filed: May 15, 2015

(30) Foreign Application Priority Data
Sep. 5, 2014 (KR) 10-2014-0118898

(51) Int. Cl. H01L 33/00; H01L 33/40; H01L 33/04

(52) U.S. Cl. CPC H01L 33/002; H01L 33/04; H01L 33/40

(57) ABSTRACT

A semiconductor light emitting device includes: a light emitting structure including a first conductivity-type semiconductor layer, a second conductivity-type semiconductor layer, and an active layer disposed therebetween; a first electrode disposed on the light emitting structure to be electrically connected to the first conductivity-type semiconductor layer; and a second electrode disposed on the light emitting structure to be electrically connected to the second conductivity-type semiconductor layer. The second electrode includes a first layer disposed on the second conductivity-type semiconductor layer, and a second layer disposed on the first layer, having a sheet resistance higher than that of the first layer, and having a thickness less than that of the first layer.

### CROSS-REFERENCE TO RELATED APPLICATION

This application claims the priority to and benefit of Korean Patent Application No. 10-2014-0118898 filed on Sep. 5, 2014, with the Korean Intellectual Property Office, the disclosure of which is incorporated herein by reference.

### BACKGROUND

The present disclosure relates to a semiconductor light emitting device.

In general, nitride semiconductors have been widely used for green or blue light emitting diodes (LED) or laser diodes (LD) provided as light sources for full-color displays, image scanners, a variety of signal systems, and optical communications devices. Such semiconductor light emitting devices may be provided as light emitting devices having an active layer emitting light in various colors including blue and green through recombination of electrons and holes.

The range of applications of semiconductor light emitting devices has been extended, thus encouraging research into using semiconductor light emitting devices as general lighting apparatuses and electrical light sources. In recent times, moreover, the boundaries of usage thereof have been extended into the high current/high output field. Accordingly, research on semiconductor light emitting devices has been conducted in earnest in order to ameliorate light emitting efficiency and quality thereof. In particular, semiconductor light emitting devices having enhanced luminance thereof by increasing a light emitting area within an active layer are being suggested.

### SUMMARY

An aspect of the present disclosure may provide a semiconductor light emitting device having enhanced luminance thereof by increasing a light emitting area within an active layer.

According to an aspect of the present disclosure, a semiconductor light emitting device may include: a light emitting structure including a first conductivity-type semiconductor layer, a second conductivity-type semiconductor layer, and an active layer disposed therebetween; a first electrode disposed on the light emitting structure to be electrically connected to the first conductivity-type semiconductor layer; and a second electrode disposed on the light emitting structure to be electrically connected to the second conductivity-type semiconductor layer. The second electrode may include a first layer disposed on the second conductivity-type semiconductor layer, and a second layer disposed on the first layer, having a sheet resistance higher than that of the first layer, and having a thickness less than that of the first layer.

The second layer may have an area smaller than that of the first layer.

Currents applied to the light emitting structure through the first electrode and the second electrode may flow at an interface between the first layer and the second layer in a direction parallel to the interface between the first layer and the second layer.

The first layer may be a reflective electrode in ohmic contact with the second conductivity-type semiconductor layer.

The first layer may include silver (Ag).

The second layer may include at least one of chromium (Cr), indium tin oxide (ITO), titanium (Ti), tungsten (W), titanium-tungsten (TiW), platinum (Pt), and zinc oxide (ZnO).

The thickness of the second layer may be less than a half of a thickness of the first layer.

The thickness of the second layer may be less than 1,000 angstrom (Å).

The first electrode may be electrically connected to the first conductivity-type semiconductor layer through at least one contact hole.

The first conductivity-type semiconductor layer may include a plurality of nanocores, and the active layer and the second conductivity-type semiconductor layer may be sequentially disposed on the plurality of nanocores.

The second electrode may include a third layer disposed on the second layer and including an Ag-palladium (Pd)-copper (Cu) alloy.

According to another aspect of the present disclosure, a semiconductor light emitting device may include: a light emitting structure including a first conductivity-type semiconductor layer, an active layer, and a second conductivity-type semiconductor layer sequentially laminated therein; a first electrode disposed on the light emitting structure to be electrically connected to the first conductivity-type semiconductor layer; and a second electrode disposed on the light emitting structure to be electrically connected to the second conductivity-type semiconductor layer. The second electrode may include a first layer disposed on the second conductivity-type semiconductor layer, and a second layer disposed on the first layer, having an area smaller than that of the first layer, and having a sheet resistance level lower than that of the first layer.

The second layer may have a thickness less than that of the first layer.

The thickness of the second layer may be a half of a thickness of the first layer.

Currents applied to the light emitting structure through the first electrode and the second electrode may flow at an interface between the first layer and the second layer in a direction parallel to the interface between the first layer and the second layer.

According to still another aspect of the present disclosure, a semiconductor light emitting device may include: a light emitting structure including a first conductivity-type semiconductor layer, a second conductivity-type semiconductor layer, and an active layer disposed therebetween; a first electrode electrically connected to the first conductivity-type semiconductor layer; and a second electrode including first and second layers and electrically connected to the second conductivity-type semiconductor layer. The first layer of the second electrode may be interposed between the second layer of the second electrode and the second conductivity-type semiconductor layer. A sheet resistance of the second layer may be greater than that of the first layer.

A thickness of the second layer may be less than a thickness of the first layer.

The thickness of the second layer may be less than a half of the thickness of the first layer.

The thickness of the second layer may be less than 1,000 angstrom (Å).

The second layer may have an area less than that of the first layer.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a cross-sectional view illustrating a semiconductor light emitting device according to an exemplary embodiment in the present disclosure;

FIGS. 2 and 3 are cross-sectional views illustrating current flow in a semiconductor light emitting device according to exemplary embodiments in the present disclosure;

FIGS. 4A and 4B are views illustrating a phenomenon of current spreading occurring in a semiconductor light emitting device according to exemplary embodiments in the present disclosure;

FIGS. 5 through 9 are cross-sectional views illustrating semiconductor light emitting devices according to exemplary embodiments in the present disclosure;

FIG. 10 is a cross-sectional view illustrating a light emitting device package including a semiconductor light emitting device according to an exemplary embodiment in the present disclosure;

FIGS. 11 and 12 are cross-sectional views illustrating examples of backlight units using semiconductor light emitting devices according to exemplary embodiments in the present disclosure;

FIG. 13 is an exploded perspective view illustrating an example of a lighting apparatus using a semiconductor light emitting device according to an exemplary embodiment in the present disclosure; and

FIG. 14 is a view illustrating an example of a headlamp using a semiconductor light emitting device according to an exemplary embodiment in the present disclosure.

### DETAILED DESCRIPTION

Exemplary embodiments in the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

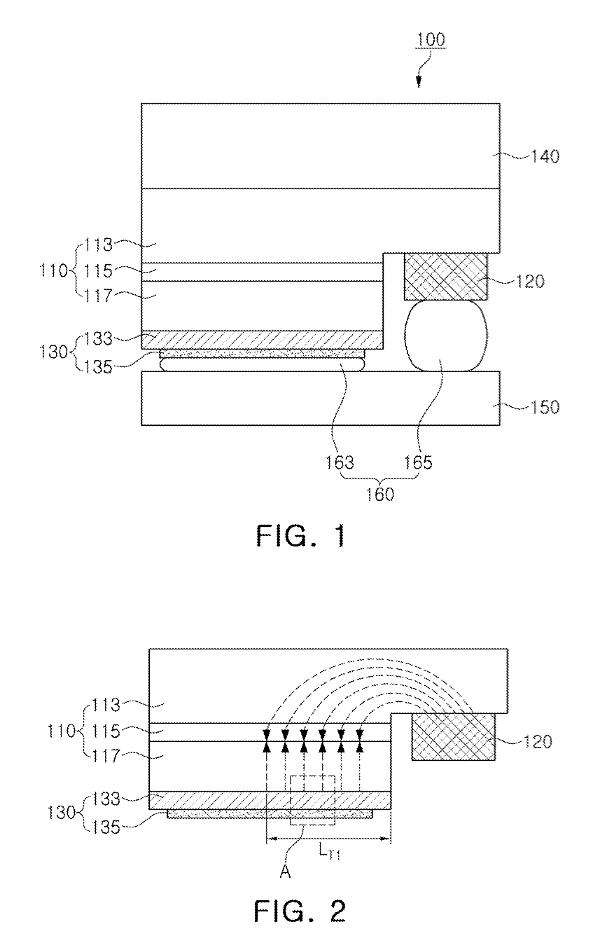

FIG. 1 is a cross-sectional view illustrating a semiconductor light emitting device according to an exemplary embodiment in the present disclosure.

Referring to FIG. 1, a semiconductor light emitting device 100 according to an exemplary embodiment in the present disclosure may include a light emitting structure 110 including a first conductivity-type semiconductor layer 113, an active layer 115, and a second conductivity-type semiconductor layer 117, a first electrode 120 electrically connected to the first conductivity-type semiconductor layer 113, and a second electrode 130 electrically connected to the second conductivity-type semiconductor layer 117. The emitting structure 110 may be provided with a support substrate 140 attached to a surface thereof.

The light emitting device 100 according to the exemplary embodiment illustrated in FIG. 1 may have a flip-chip structure in which light is emitted through the support substrate 140. Accordingly, as illustrated in FIG. 1, the first electrode 120 and the second electrode 130 may be attached to a circuit substrate 150 through a solder bump 160, or the like. Due to an electrical signal applied to the circuit substrate 150, electron-hole recombination may occur in the active layer 115. Light generated by such electron-hole recombination may be transmitted upwardly through the support substrate 140 having light transmissivity, or may be transmitted upwardly through being reflected by the second electrode 130. Accordingly, the second electrode 130 may include a material having relatively high reflectivity.

In the exemplary embodiment, the first conductivity-type semiconductor layer 113 may be an n-type nitride semiconductor layer, and the second conductivity-type semiconductor layer 117 may be a p-type nitride semiconductor layer. Due to characteristics of the p-type nitride semiconductor layer, such as having a resistance level higher than that of the n-type nitride semiconductor layer, an issue of ohmic contact may occur between the second conductivity-type semiconductor layer 117 and the second electrode 130. However, in the exemplary embodiment illustrated in FIG. 1, since an area of the second electrode 130 is substantially the same as that of the second conductivity-type semiconductor layer 117, ohmic contact between the second conductivity-type semiconductor layer 117 and the second electrode 130 may be secured.

Also, due to the nature of the semiconductor light emitting device 100 in which light is mainly extracted upwardly from an upper portion of the semiconductor light emitting device 100 to which the substrate support 140 is attached, output efficiency of the semiconductor light emitting device 100 may be enhanced by forming the second electrode 130, using a material having high reflectivity. The second electrode 130 may include a first layer 133 forming ohmic contact with the second conductivity-type semiconductor layer 117 and a second layer 135 disposed on the first layer 133. The expression “the second layer 135 is disposed on the first layer 133” may be interpreted as referring to a structure in which the second layer 135 is disposed on a surface of the first layer 133 not in contact with the second conductivity-type semiconductor layer 117.

To externally emit light generated in the active layer 115 through electron-hole recombination by reflection through the support substrate 140, the first layer 133 included in the second electrode 130 may include a material having relatively high reflectivity, such as silver (Ag), nickel (Ni), aluminum (Al), rhodium (Rh), palladium (Pd), Iridium (Ir), ruthenium (Ru), magnesium (Mg), zinc (Zn), platinum (Pt), or gold (Au). On the other hand, the second layer 135 disposed on the first layer 133 may be a layer provided in order to improve luminance by enhancing current spreading characteristics throughout the second electrode 130. In general, since a transfer speed of a hole is slower than that of an electrode, a light emitting area of the active layer 115 may be efficiently increased by forming the second electrode 130 disposed on the second conductivity-type semiconductor layer 117 in a multilayer structure including the first layer 133 and the second layer 135.

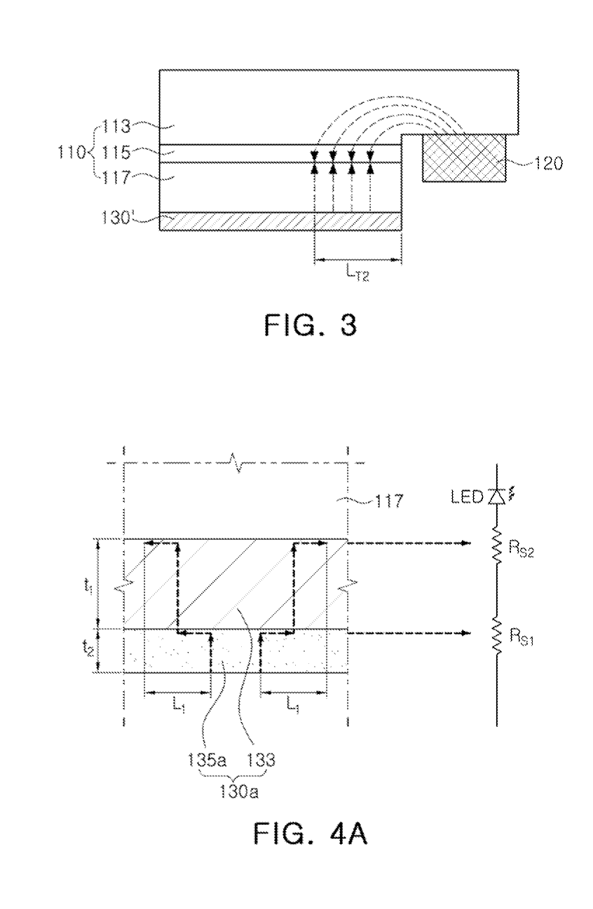

In the exemplary embodiment, the second layer 135 may have a sheet resistance level higher than that of the material included in the first layer 133. By forming the second layer 135 using such a material having a sheet resistance level higher than that of the first layer 133, currents may be induced to spread in a direction parallel to an interface between the first layer 133 and the second layer 135. Accordingly, electron-hole recombination occurring in the active layer 115 due to an electrical signal applied to the first electrode 120 and the second electrode 130 may be mitigated in an area adjacent to the first electrode 120 and the second electrode 130 in which electron-hole recombination is concentrated, and thus luminance of the semiconductor light emitting device 100 may be enhanced by increasing the light emitting area of the active layer 115 in which electron-hole recombination occurs. Hereinafter, current spreading due to the multilayer structure of the first layer 133 and the second layer 135 and the effect of luminance enhancements thereof will be described with reference to FIGS. 2 and 3.

The first conductivity-type semiconductor layer 113 and the second conductivity-type semiconductor layer 117 of the light emitting structure 110 may be the n-type semiconductor layer and the p-type semiconductor layer, respectively, as previously described. For example, the first conductivity-type semiconductor layer 113 and the second conductivity-type semiconductor layer 117 may be formed of a Group III nitride semiconductor, for example, a material having a composition of AlₓIn_{y}Ga_{1-x-y}N, wherein 0≦x≦1, 0≦y≦1, 0≦x+y≦1. However, the type of material forming the first conductivity-type semiconductor layer 113 and the second conductivity-type semiconductor layer 117 is not limited thereto, and a material such as an AlGaInP-based semiconductor or an AlGaAs-based semiconductor may be used.

The first conductivity-type semiconductor layer 113 and the second conductivity-type semiconductor layer 117 may have a monolayer structure. Alternatively, the first conductivity-type semiconductor layer 113 and the second conductivity-type semiconductor layer 117 may have a multilayer structure having different compositions, thicknesses, and the like, as necessary. For example, the first conductivity-type semiconductor layer 113 and the second conductivity-type semiconductor layer 117 may have a carrier injection layer capable of enhancing injection efficiency of electrons and holes, and may further have a superlattice structure in various forms.

The first conductivity-type semiconductor layer 113 may further include a current spreading layer in an area adjacent to the active layer 115. The current spreading layer may have a structure in which a plurality of InₓAl_{y}Ga_{(1-x-y)}N layers having different compositions or different impurity contents are iteratively laminated, or may have an insulating layer partially formed therein.

The second conductivity-type semiconductor layer 117 may further include an electron blocking layer in an area adjacent to the active layer 115. The electron blocking layer may have a structure in which a plurality of InₓAl_{y}Ga_{(1-x-y)}N layers having different compositions are laminated, or may have one or more layers including Al_{y}Ga_{(1-y)}N. Since the electron blocking layer has a bandgap wider than that of the active layer 115, transfer of electrons from the active layer 115 to the second conductivity-type semiconductor layer 117 may be prevented.

In the exemplary embodiment, the light emitting structure 110 may be formed by using a metal-organic chemical vapor deposition (MOCVD) apparatus. In order to manufacture the light emitting structure 110, an organic metal compound gas, for example, trimethyl gallium (TMG) or trimethyl aluminum (TMA), and a nitrogen-containing gas, for example, ammonia (NH₃) may be supplied to a reaction container in which a growth substrate is installed as reactive gases, the growth substrate may be maintained at a relatively high temperature in a range of 900° C. to 1,100° C., and an impurity gas may be supplied as necessary while a gallium nitride (GaN)-based compound semiconductor is being grown, so as to laminate the GaN-based compound semiconductor as an undoped, n-type, or p-type semiconductor. Silicon (Si) may be a well known n-type impurity, and a p-type impurity may include Zn, cadmium (Cd), beryllium (Be), Mg, calcium (Ca), barium (Ba), and the like. Among these, Mg and Zn may be mainly used.

Also, the active layer 115 disposed between the first and second conductivity-type semiconductor layers 113 and 117 may have a multi-quantum well (MQW) structure in which a quantum well layer and a quantum barrier layer are laminated in an alternating manner. In a case in which the active layer 115 includes a nitride semiconductor, an MQW structure in which GaN/InGaN layers are laminated in an alternating manner may be employed. According to exemplary embodiments, a single quantum well (SQW) structure may also be used.

FIGS. 2 and 3 are cross-sectional views illustrating current flow of a semiconductor light emitting device according to exemplary embodiments in the present disclosure. In the semiconductor light emitting device according to the exemplary embodiment illustrated in FIG. 2, the second electrode 130 having the first layer 133 and the second layer 135 formed of a material having a sheet resistance level higher than that of the first layer 133 may be disposed on the second conductivity-type semiconductor layer 117. On the other hand, in the semiconductor light emitting device according to the exemplary embodiment illustrated in FIG. 3, a second electrode 130′ having a monolayer structure may be disposed on the second conductivity-type semiconductor layer 117.

Referring to FIG. 2, since the first layer 133 and the second layer 135 included in the second electrode 130 have different sheet resistance levels from one another, current spreading in which currents applied to the second electrode 130 at the interface between the first layer 133 and the second layer 135 flow in a direction parallel to the interface therebetween may occur. Accordingly, a transfer length L_{T1} of the second electrode 130 may be increased.

Referring to FIG. 3, since the second electrode 130′ has the monolayer structure, currents generated by an electrical signal applied to the second electrode 130′ may flow in a direction perpendicular to an interface between the second electrode 130′ and the second conductivity-type semiconductor layer 117, rather than a direction parallel to the interface between the second electrode 130′ and the second conductivity-type semiconductor layer 117. Accordingly, a transfer length L_{T2} of the second electrode 130′ may have a value smaller than the transfer length L_{T1} of the second electrode 130 according to the exemplary embodiment illustrated in FIG. 2.

In other words, the transfer length L_{T1} of the second electrode 130 and the transfer length L_{T2} of the second electrode 130′ according to the exemplary embodiments illustrated in FIGS. 2 and 3 may vary based on the presence of the second layer 135. The transfer length L_{T1} of the second electrode 130 including the second layer 135 may be greater than the transfer length L_{T2} of the second electrode 130′ having the monolayer structure. Accordingly, the active layer 115 of the semiconductor light emitting device 100 having the second electrode 130 including the second layer 135 may have a relatively great light emitting area, and thereby relatively high luminance.

In order to efficiently enhance luminance of the semiconductor light emitting device 100 using current spreading occurring in the second electrode 130, the second layer 135 may have a sheet resistance level higher than that of the first layer 133. As described hereinbefore, the first layer 133 may include a material having relatively high reflectivity to efficiently reflect light generated in the active layer 115, and may include Ag by way of example. Here, the second layer 135 may include a material having a sheet resistance level higher than that of Ag, and may include, for example, chromium (Cr), titanium (Ti), tungsten (W), titanium-tungsten (TiW), indium tin oxide (ITO), Pt, and zinc oxide (ZnO).

Also, the second layer 135 may have an area and a thickness, at least one of which being smaller than an area and a thickness of the first layer 133. Although FIGS. 1 and 2 illustrate the second layer 135 having a thickness and an area smaller than those of the first layer 133, the second layer 135 may also have an area the same as and a thickness less than those of the first layer 133. In addition, the second layer 135 may also have an area smaller than and a thickness equal to or greater than those of the first layer 133.

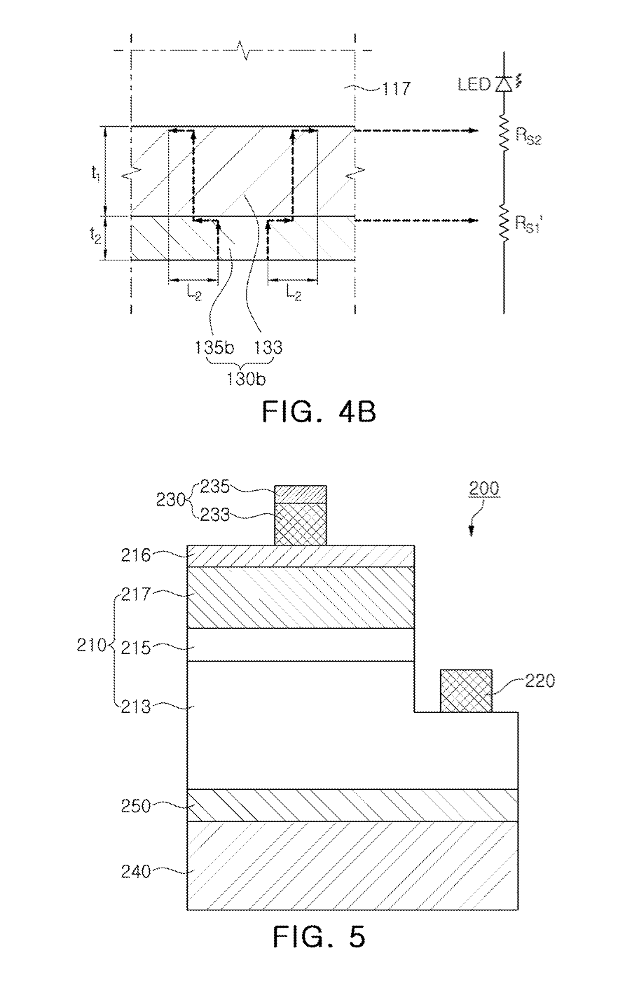

Hereinafter, current spreading which may occur in the second electrode 130 having the laminate structure including the first layer 133 and the second layer 135 will be described with reference to FIGS. 4A and 4B.

FIGS. 4A and 4B are views illustrating a phenomenon of current spreading occurring in a semiconductor light emitting device according to exemplary embodiments in the present disclosure. FIGS. 4A and 4B are enlarged views illustrating part A of FIG. 2.

Referring to FIG. 4A, the second electrode 130a may include the first layer 133 forming ohmic contact with the second conductivity-type semiconductor layer 117 and the second layer 135a. The first layer 133 may include Ag having relatively high reflectivity to efficiently reflect light generated in the active layer 115, and the second layer 135a may include a material having a sheet resistance level higher than that of Ag, for example, Cr.

In the exemplary embodiment illustrated in FIG. 4A, a thickness t2 of the second layer 135a may be less than 1,000 angstrom (Å), and a thickness t1 of the first layer 133 may be greater than that of the second layer 135a. As illustrated in FIG. 4A, since the second layer 135a has the sheet resistance level higher than that of the first layer 133, interface resistance R_{S1} may occur at the interface between the first layer 133 and the second layer 135a. That is, currents generated by an electrical signal applied through the second electrode 130a may flow into the light emitting structure 110 through the interface resistance R_{S1} between the first layer 133 and the second layer 135a and interface resistance R_{S2} between the first layer 133 and the second conductivity-type semiconductor layer 117.

Likewise, in the exemplary embodiment illustrated in FIG. 4B, the thickness t2 of the second layer 135b may be less than 1,000 Å, and the thickness t1 of the first layer 133 may be greater than that of the second layer 135b. Also, currents generated by the electrical signal applied through the second electrode 130b may flow into the light emitting structure 110 through interface resistance R_{S1}′ between the first layer 133 and the second layer 135b and the interface resistance R_{S2} between the first layer 133 and the second conductivity-type semiconductor layer 117. However, dissimilar to the exemplary embodiment illustrated in FIG. 4A, the second layer 135b in the exemplary embodiment illustrated in FIG. 4B may include Ni having a sheet resistance level lower than that of Cr.

In comparing the exemplary embodiment of FIG. 4A in which the second layer 135a is formed of Cr on the first layer 133 including Ag and the exemplary embodiment of FIG. 4B in which the second layer 135b is formed of Ni on the first layer 133 including Ag, the interface resistance R_{S1} between the first layer 133 and the second layer 135a and the interface resistance R_{S1}′ between the first layer 133 and the second layer 135b may be different from one another. In other words, the interface resistance R_{S1} between the first layer 133 and the second layer 135a in the exemplary embodiment of FIG. 4A may be lower than the interface resistance R_{S1}′ between the first layer 133 and the second layer 135b in the exemplary embodiment of FIG. 4B. Accordingly, a sum of the lengths L1 of currents flowing at the interface between the first layer 133 and the second layer 135a in the direction parallel to the interface between the first layer 133 and the second layer 135a in the exemplary embodiment of FIG. 4A may be greater than a sum of the lengths L2 of currents flowing at an interface between the first layer 133 and the second layer 135b in a direction parallel to the interface between the first layer 133 and the second layer 135b in the exemplary embodiment of FIG. 4B.

For example, the interface resistivity at the interface between the first layer 133 and the second layer 135a according to the exemplary embodiment of FIG. 4A may be 1.2*10⁻² Ω*cm², and the interface resistivity at the interface between the first layer 133 and the second layer 135b according to the exemplary embodiment of FIG. 4B may be 4.7*10⁻³ Ω*cm². Here, when respective transfer lengths of the second electrodes 130a and 130b are measured by using a transfer length method (TLM), the transfer length of the second electrode 130a according to the exemplary embodiment of FIG. 4A may be 23 micrometers (μm), and the transfer length of the second electrode 130b according to the exemplary embodiment of FIG. 4B may be 15 μm. In other words, as the interface resistance between the first layer 133 and the second layer 135a is increased as in the exemplary embodiment of FIG. 4A, the transfer length of the second electrode 130a may also be increased, and thereby a light emitting area of the active layer 115 may be increased and luminance may also be enhanced.

FIGS. 5 through 8 are cross-sectional views illustrating semiconductor light emitting devices according to exemplary embodiments in the present disclosure.

As illustrated in FIG. 5, a semiconductor light emitting device 200 according to an exemplary embodiment in the present disclosure may include a light emitting structure 210 formed on a substrate 240. The light emitting structure 210 may include a first conductivity-type semiconductor layer 213, an active layer 215, and a second conductivity-type semiconductor layer 217.

Also, an ohmic contact layer 260 may be formed on the second conductivity-type semiconductor layer 217. First and second electrodes 220 and 230 may be formed on top surfaces of the first conductivity-type semiconductor layer 213 and the ohmic contact layer 260, respectively. The second electrode 230 may include a first layer 233 in contact with the ohmic contact layer 260 and a second layer 235 disposed on the first layer 233.

At least one of an insulating substrate, a conductive substrate, and a semiconductor substrate may be used as the substrate 240 according to various exemplary embodiments. For example, the substrate 240 may use a material such as sapphire, silicon carbide (SiC), Si, magnesium aluminate (MgAl₂O₄), magnesium oxide (MgO), lithium aluminate (LiAlO₂), lithium gallium oxide (LiGaO₂), or GaN. For epitaxial growth of a GaN material, a GaN substrate, a homogeneous substrate, may be selected as the substrate 240. Also, as a heterogeneous substrate, a sapphire substrate, a SiC substrate, or the like, may be selected. In a case of using the heterogeneous substrate, defects such as dislocation may be increased due to a difference between lattice constants of a substrate material and a thin film material. In addition, a difference between thermal expansion coefficients of the substrate material and the thin film material may cause warpage when temperature changes, and such warpage may cause cracks in the thin film. To solve such issues, a buffer layer 250 may be disposed between the substrate 240 and the GaN-based light emitting structure 210.

When the light emitting structure 210 including GaN is grown on the heterogeneous substrate, dislocation density may be increased due to a lattice constant mismatch between the substrate material and the thin film material, and cracks and warpage may occur due to a difference between the thermal expansion coefficients. To prevent dislocation of and cracks in the light emitting structure 210, the buffer layer 250 may be disposed between the substrate 240 and the light emitting structure 210. The buffer layer 250 may adjust a degree of warpage of the substrate while the active layer is grown, to reduce wavelength dispersion of a wafer.

The buffer layer 250 may use AlₓIn_{y}Ga_{1-x-y}N, wherein 0≦x≦1, 0≦y≦1, more particularly, GaN, aluminum nitride (AlN), aluminum gallium nitride (AlGaN), indium gallium nitride (InGaN), or indium gallium nitride aluminum nitride (InGaNAlN), and as necessary, may use a material, for example, zirconium diboride (ZrB2), hafnium diboride (HfB2), zirconium nitride (ZrN), hafnium nitride (HfN), or titanium nitride (TiN) Further, the buffer layer 250 may be formed by combining a plurality of layers, or gradually changing a composition thereof.

Thermal expansion coefficients between a Si substrate and GaN are significantly different from one another. In a case in which a GaN-based thin film is grown on a Si substrate, when the GaN-based thin film is grown at a relatively high temperature and cooled to room temperature, cracks may be caused by tensile stress applied to the GaN-based thin film due to the difference in the thermal expansion coefficients between the Si substrate and GaN-based thin film. In order to avoid such cracks, a method of growing the GaN-based thin film that allows compressive stress to be applied to the GaN-based thin film during the growth of the GaN-based thin film may be used to compensate for tensile stress. In addition, due to a difference between lattice constants of Si and GaN, defects may be highly likely to occur. In a case of using the Si substrate, a buffer layer 250 having a composite structure may be used in order to simultaneously control defects and stress for restraining warpage.

To form the buffer layer 250, an AlN layer may be initially formed on the substrate 240. A material not including Ga may be used to avoid a reaction between Si and Ga. Aside from AlN, a material such as SiC may also be used. The AlN layer may be grown at a temperature in a range of 400° C. to 1,300° C. using an Al source and an N source. As necessary, an intermediate AlGaN layer may be interposed between a plurality of AlN layers in order to control stress.

The light emitting structure 210 may include the first and second conductivity-type semiconductor layers 213 and 217, and the active layer 215. The first and second conductivity-type semiconductor layers 213 and 217 may be formed of semiconductors doped with n-type and p-type impurities, respectively. However, the type of the first and second conductivity-type semiconductor layers 213 and 217 is not limited thereto. The first and second conductivity-type semiconductor layers 213 and 217 may also be formed in a converse manner, for example, the semiconductors doped with p-type and n-type impurities, respectively. For example, the first and second conductivity-type semiconductor layers 213 and 217 may be formed of a Group III nitride semiconductor, for example, a material having a composition of AlₓIn_{y}Ga_{1-x-y}N, wherein 0≦x≦1, 0≦y≦1, 0≦x+y≦1. However, the type of material forming the first and second conductivity-type semiconductor layers 213 and 217 is not limited thereto, and a material such as an aluminum gallium indium phosphide (AlGaInP)-based semiconductor or an aluminum gallium arsenide (AlGaAs)-based semiconductor may also be used.

The first and second conductivity-type semiconductor layers 213 and 217 may have a monolayer structure. Alternatively, the first and second conductivity-type semiconductor layers 213 and 217 may also have a multilayer structure having different compositions, thicknesses, or the like, as necessary. For example, the first and second conductivity-type semiconductor layers 213 and 217 may have a carrier injection layer capable of enhancing injection efficiency of electrons and holes, and may further have a superlattice structure in various forms.

The first conductivity-type semiconductor layer 213 may further include a current spreading layer in an area adjacent to the active layer 215. The current spreading layer may have a structure in which a plurality of InₓAl_{y}Ga_{(1-x-y)}N layers having different compositions or different impurity contents are iteratively laminated, or may have an insulating layer partially formed therein.

The second conductivity-type semiconductor layer 217 may further include an electron blocking layer in an area adjacent to the active layer 215. The electron blocking layer may have a structure in which a plurality of InₓAl_{y}Ga_{(1-x-y)}N layers having different compositions are laminated, or may have one or more layers including Al_{y}Ga_{(1-y)}N. Since the electron blocking layer has a bandgap wider than that of the active layer 215, transfer of electrons from the active layer 215 to the second conductivity-type semiconductor layer 217 may be prevented.

In the exemplary embodiment, the light emitting structure 210 may be formed by using an MOCVD apparatus. In order to manufacture the light emitting structure 210, an organic metal compound gas, for example, TMG or TMA, and a nitrogen-containing gas, for example, NH₃, may be supplied to a reaction container in which a growth substrate is installed as reactive gases, the growth substrate may be maintained at a relatively high temperature in a range of 900° C. to 1,100° C., and an impurity gas may be supplied as necessary while a GaN-based compound semiconductor is being grown, so as to laminate the GaN-based compound semiconductor as an undoped, n-type, or p-type semiconductor. Si may be a well known n-type impurity, and a p-type impurity may include Zn, Cd, Be, Mg, Ca, Ba, and the like. Among these, Mg and Zn may be mainly used.

Also, the active layer 215 disposed between the first and second conductivity-type semiconductor layers 213 and 217 may have an MQW structure in which a quantum well layer and a quantum barrier layer are laminated in an alternating manner. For example, in a case in which the active layer 215 includes a nitride semiconductor, an MQW structure in which GaN/InGaN layers are laminated in an alternating manner may be provided. According to exemplary embodiments, an SQW structure may also be used.

The ohmic-contact layer 260 may have a relatively high impurity concentration to have relatively low ohmic-contact resistance, thereby lowering an operating voltage of the semiconductor light emitting device and enhancing device characteristics. The ohmic-contact layer 260 may be formed of a GaN layer, an InGaN layer, a ZnO layer, or a graphene layer.

The first or second electrode 220 and 230 may include a material such as Ag, Ni, Al, Rh, Pd, Ir, Ru, Mg, Zn, Pt, or Au. In particular, according to the exemplary embodiment, the second electrode 230 may have a laminate structure in which the first layer 233 and the second layer 235 are laminated. The second layer 235 may include a material having a sheet resistance level higher than that of the first layer 233. For example, in a case in which the first layer 233 includes Ag, the second layer 235 may include a material such as Cr, Ti, W, TiW, ITO, Pt, or ZnO.

By forming the second layer 235, interface resistance occurring at an interface between the first layer 233 and the second layer 235 may be increased, and thereby currents may spread widely. In other words, the second layer 235 may serve as a current spreading layer. Currents may flow at the interface between the first layer 233 and the second layer 235 in a direction parallel thereto due to the interface resistance therebetween. Accordingly, an area of the active layer 215 in which electron-hole recombination occurs may be increased, and thereby luminance of the semiconductor light emitting device 200 may be enhanced.

A thickness of the second layer 235 may be less than that of the first layer 233. In a case in which the thickness of the second layer 235 is excessively great, a level of voltage required for driving the semiconductor light emitting device 200 may be increased due to the second layer 235, and thus an amount of power consumed may be increased. Accordingly, the thickness of the second layer 235 may be less than that of the first layer 233, and may be less than a half of the thickness of the first layer 233, or less than 1,000 Å. Also, in order to enhance a current spreading phenomenon at the interface between the first layer 233 and the second layer 235, an area of the first layer 233 may be smaller than that of the second layer 235.

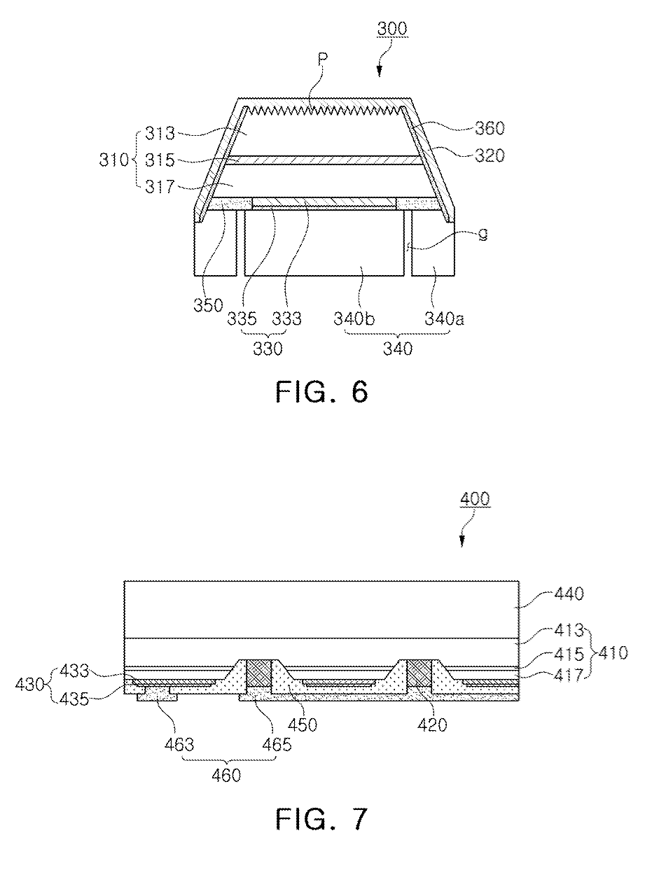

Referring to FIG. 6, a semiconductor light emitting device 300 according to an exemplary embodiment in the present disclosure may include a light emitting structure 310 and a support structure 340. The light emitting structure 310 may include a first conductivity-type semiconductor layer 313, a second conductivity-type semiconductor layer 317, and an active layer 315 disposed therebetween. The light emitting structure 310 may include a first surface and a second surface provided by the first conductivity-type semiconductor layer 313 and the second conductivity-type semiconductor layer 317, respectively, and lateral surfaces disposed therebetween.

The light emitting structure 310 may include a nitride semiconductor satisfying AlₓIn_{y}Ga_{1-x-y}N, wherein 0≦x≦1, 0≦y≦1, 0≦x+y≦1. The first and second conductivity-type semiconductor layers 315 and 317 constituting the light emitting structure 310 may be an n-type semiconductor layer and a p-type semiconductor layer, respectively; however, the type of the first and second conductivity-type semiconductor layers 315 and 317 is not limited thereto. The first and second conductivity-type semiconductor layers 315 and 317 may have a monolayer structure and may alternatively have a multilayer structure having different compositions and/or different doping concentrations of impurities. For example, the first conductivity-type semiconductor layer 315 may be n-type GaN, and the second conductivity-type semiconductor layers 317 may be p-type GaN. In the active layer 315, light having a predetermined wavelength may be generated by recombining electrons and holes supplied from the first and second conductivity-type semiconductor layers 315 and 317. For example, the active layer 315 may have an MQW structure in which a quantum well layer and a quantum barrier layer are laminated in an alternating manner. In a case in which the light emitting structure 310 is a nitride semiconductor, the active layer 315 may have an MQW structure in which GaN/InGaN layers are laminated in an alternating manner. However, the structure of the active layer 315 is not limited thereto, and a single quantum well (SQW) structure may also be used as necessary. According to exemplary embodiments, the light emitting structure 310 may use a semiconductor material having different compositions.

For example, aside from the nitride semiconductor, an AlInGaP-based semiconductor or an AlInGaAs-based semiconductor may be used.

The light emitting structure 310 may be grown on a separate growth substrate, and then attached to the support structure 340. The growth substrate may be removed from the light emitting structure 310, and an unevenness structure P may be formed on a surface, for example, the first surface provided by the first conductivity-type semiconductor layer 313, from which the growth substrate is removed, in order to enhance light extraction efficiency. Such an unevenness structure P may be obtained by undertaking wet etching or dry etching using plasma on the second conductivity-type semiconductor layer 317, subsequently to the growth substrate being removed from the light emitting structure 310 or during the removing process.

Lateral insulating layers 360 may be formed on the lateral surfaces of the light emitting structure 310. As illustrated in FIG. 6, the lateral insulating layers 360 may be disposed on the entirety of the lateral surfaces of the light emitting structure 310, and may be provided as passivation layers. The lateral insulating layer 360 may be a silicon oxide or a silicon nitride. Deposition of the lateral insulating layer 360 may be facilitated by forming the lateral surface of the light emitting structure 310 in an inclined manner.

According to the exemplary embodiment, a first electrode 320 and a second electrode 330 may be connected to the first conductivity-type semiconductor layer 313 and the second conductivity-type semiconductor layer 317, respectively, through the first surface and the second surface of the light emitting structure 310, respectively. As illustrated in FIG. 6, since respective connection positions of the first and second electrodes 320 and 330 are disposed in a vertical manner, relatively uniform current spreading may be achieved in the light emitting structure 310, in particular, in the entirety of the active layer.

Also, the second electrode 330 may include a first layer 333 directly connected to the second conductivity-type semiconductor layer 317 and a second layer 335 attached to the first layer 333. The second layer 335 may include a material having a sheet resistance level higher than that of the first layer 333. According to various exemplary embodiments, the second layer 335 may have an area and a thickness, at least one of which being smaller than an area and a thickness of the first layer 333. The thickness of the second layer 335 may be limited to be less than a half of the thickness of the first layer 333 or less than 1,000 Å.

Interface resistance may occur at an interface between the first layer 333 and the second layer 335 due to a difference between sheet resistance levels of the first and second layers 333 and 335. Currents applied to the second electrode 330 may flow at the interface between the first and second layers 333 and 335 in a direction parallel thereto, rather than in a direction in which the light emitting structure 310 is laminated, due to the interface resistance therebetween. Accordingly, currents may uniformly spread in a horizontal direction, an area of the active layer in which electron-hole recombination occurs may be increased, and thereby overall luminance may be enhanced throughout the semiconductor light emitting device 300.

The first electrode 320 may include a transparent electrode. The first electrode 320 may be entirely formed of a transparent electrode, or a connected area of the first surface of the light emitting structure 310 may be formed of a transparent electrode, and another area of the first surface may be formed of a metal electrode, as necessary. The first electrode 320 having characteristics as a transparent electrode may include at least one material selected from a group consisting of ITO, zinc-doped indium tin oxide (ZITO), zinc indium oxide (ZIO), gallium Indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, or zinc magnesium oxide (Zn₍₁₋ₓ₎MgₓO), wherein 0≦x≦1. As necessary, the first electrode 320 may include graphene.

The second electrode 330 may be formed on the second surface of the light emitting structure 310. The first layer 333 of the second electrode 330 may use a material capable of ohmic contact and having relatively high reflectivity. For example, the first layer 333 may include a material such as Ag, Ni, Al, Rh, Pd, Ir, Ru, Mg, Zn, Pt, or Au. The second layer 335 attached to the first layer 333 may include a material having a higher sheet resistance level than the first layer 333. For example, in a case in which the first layer 333 includes Ag, the second layer 335 may include a material such as Cr, Ti, TiW, ITO, ZnO, Pt, or W. Optionally, an Al—Pd—Cr alloy layer may be further disposed on the second layer 335.

Forms of the first electrode 320 and the second electrode 330 are not limited to the example illustrated in FIG. 6, and may be modified in various manners. For example, although FIG. 6 depicts the first electrode 320 as extending along the entirety of both of the lateral surfaces of the light emitting structure 310, the first electrode 320 may extend from one of the lateral surfaces to be connected to a first package electrode 340a. The second electrode 320 may be appropriately changed according to a form of a second package electrode 340b.

The support structure 340 having the first and second package electrodes 340a and 340b may be disposed on the second surface of the light emitting structure 310. The first and second package electrodes 340a and 340b may be bonded to the light emitting structure 310 by an insulating film 350 formed on the second surface of the light emitting structure 310. The insulating film 350 may be a material capable of bonding, for example, a silicon oxide, a silicon nitride, or a resin such as polymer.

As illustrated in FIG. 6, the first and second package electrodes 340a and 340b applied to the exemplary embodiment may be divided by an air gap g. In this case, the second package electrode 340b may be formed to be in contact with the insulating film 350 so as to be bonded to the light emitting structure 310.

According to the exemplary embodiment, the insulating film 350 is exemplified to have a bonding function; however, the bonding material is not limited thereto, and an additional bonding material aside from the insulating film 350 may be used to bond the first and second package electrodes 340a and 340b to the light emitting structure 310. For example, the second package electrode 340b may be attached to the second electrode 330 using a eutectic bonding material such as a gold-tin (Au—Sn) alloy or a nickel-silicide (Ni—Si) alloy.

Referring to FIG. 7, a semiconductor light emitting device 400 according to another exemplary embodiment is illustrated. The semiconductor light emitting device 400 may include a light emitting structure 410 disposed on a surface of a substrate 440, and first and second electrodes 420 and 430 disposed opposite to the substrate 440 based on the light emitting structure 410. Also, the semiconductor light emitting device 400 may include an insulating part 450 formed to cover the first and second electrodes 420 and 430. The first and second electrodes 420 and 430 may be electrically connected to a connection electrode 460 having first and second connection electrodes 465 and 463.

The light emitting structure 410 may include a first conductivity-type semiconductor layer 413, an active layer 415, and a second conductivity-type semiconductor layer 417. The first electrode 420 may be provided as a conductive via penetrating through the second conductivity-type semiconductor layer 417 and the active layer 415 to be connected to the first conductivity-type semiconductor layer 413. The second electrode 430 may be connected to the second conductivity-type semiconductor layer 417. The conductive via may include a plurality of conductive vias formed in a single light emitting device.

A conductive ohmic material may be deposited on the light emitting structure 410 to form the first and second electrodes 420 and 430. The first and second electrodes 420 and 430 may include at least one of Ag, Al, Ni, Cr, Cu, Au, Pd, Pt, Sn, Ti, W, Rh, Ir, Ru, Mg, Zn, and an alloy thereof. Also, the second electrode 430 may have a laminate structure in which a first layer 433 and a second layer 435 are laminated. The first layer 433 may be an ohmic electrode formed of Ag and laminated on the basis of the second conductivity-type semiconductor layer 417. The first layer 433 may serve as a reflective layer reflecting light generated in the active layer 415.

The second layer 435 disposed on the first layer 433 may be formed of a material having a sheet resistance level higher than that of a material included in the first layer 433. In a case in which the first layer 433 includes Ag, the second layer 435 may be formed of a material such as Cr, Ti, TiW, W, ITO, ZnO, or Pt.

A thickness of the second layer 435 may be less than a thickness of the first layer 433. In the exemplary embodiment, the thickness of the second layer 435 may be less than a half of the thickness of the first layer 433, or less than 1,000 Å. In a case in which the thickness of the second layer 435 is excessively great, a level of resistance on a path of currents formed and transferring to the second conductivity-type semiconductor layer 417 and the active layer 415 through the second layer 435 and the first layer 433 may be increased, and thereby an amount of power consumed in the semiconductor light emitting device 400 may be increased.

The insulating part 450 may be provided with an open area exposing at least portions of the first and second electrodes 420 and 430, and the first and second connection electrodes 465 and 463 may be connected to the second electrode 430 and the first electrode 420, respectively. The insulating part 450 may be deposited to have a thickness in a range of 0.01 μm to 3 μm at a temperature equal to or lower than 500° C. through a chemical vapor deposition (CVD) process using SiO₂ and/or SiN. The first and second electrodes 420 and 430 may be disposed in a single direction, and may be mounted on a lead frame, or the like, in a so-called flip chip manner.

In particular, the first electrode 420 may be provided as the conductive via penetrating through the second conductivity-type semiconductor layer 417 and the active layer 415 to be connected to the first conductivity-type semiconductor layer 413 within the light emitting structure 410, and may be connected to the first connection electrode 465. Here, such as a number, a form, a pitch, and a contact area with the first conductivity-type semiconductor layer 413 of the conductive via and the first connection electrode 465 may be appropriately adjusted in order to lower contact resistance between the conductive via and the first connection electrode 465. The conductive via and the first connection electrode 465 may be disposed in an array of rows and columns in order to improve current flow.

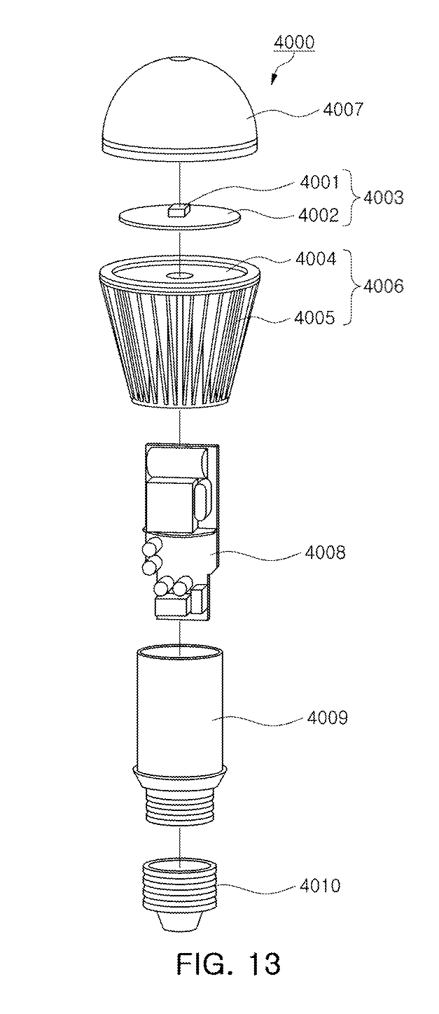

The second electrode 430 may be connected to the second connection electrode 463. In addition to having a function of forming an electrical-ohmic connection with the second conductivity-type semiconductor layer 417, the second electrode 430 may be formed of a light reflective material, whereby, as illustrated in FIG. 13, in a state in which the semiconductor light emitting device 400 is mounted in a flip chip manner, light emitted from the active layer 415 may be effectively emitted in a direction of the substrate 440.

The first and second electrodes 420 and 430 may be electrically isolated from one another by the insulating part 450. The insulating part 450 may be formed of any material having electrically insulating characteristics. However, a material having a relatively low light absorption rate may be used to form the insulating part 450. For example, a silicon oxide or a silicon nitride such as SiO₂, SiOₓN_{y}, SiₓN_{y} may be used. As necessary, a light reflective filler may be dispersed within a light transmissive material to form a light reflective structure.

The substrate 440 may have first and second surfaces opposing one another, and an unevenness structure may be formed on at least one of the first and second surfaces. The unevenness structure formed on one surface of the substrate 440 may be formed by etching a portion of the substrate 440 so as to be formed of the same material as that of the substrate 440. Alternatively, the unevenness structure may be formed of a heterogeneous material different from the material of the substrate 440. As described hereinbefore, by forming the unevenness structure on an interface between the substrate 440 and the first conductivity-type semiconductor layer 413, paths of light emitted from the active layer 415 may be diverse. Accordingly, a light absorption rate within a semiconductor layer may be reduced and a light scattering rate may be increased, and thus light extraction efficiency may be enhanced. In addition, a buffer layer may be provided between the substrate 440 and the first conductivity-type semiconductor layer 413.

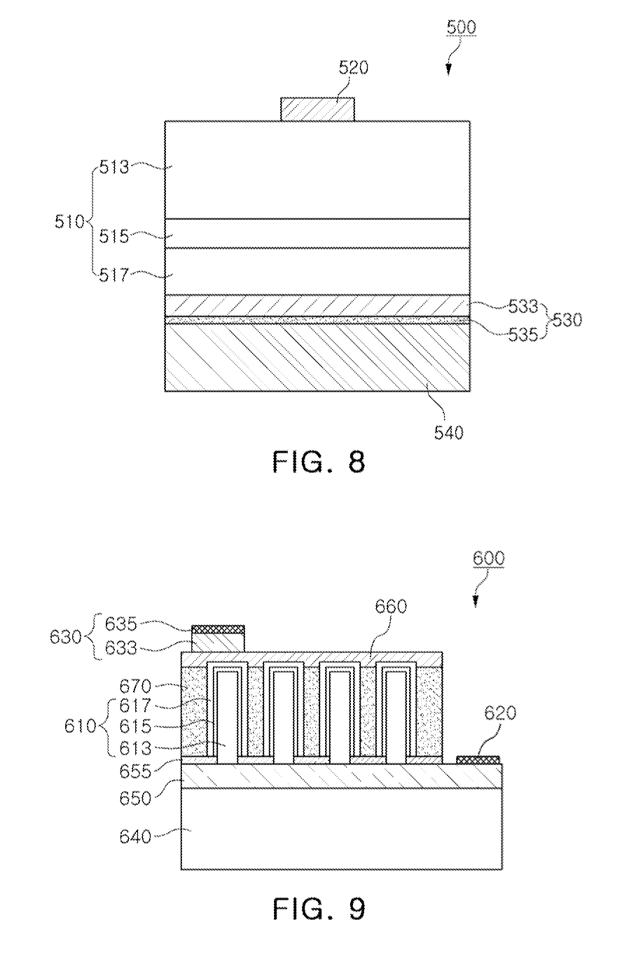

Referring to FIG. 8, a semiconductor light emitting device 500 according to an exemplary embodiment is illustrated. The semiconductor light emitting device 500 illustrated in FIG. 8 may include a light emitting structure 510 including a first conductivity-type semiconductor layer 513, an active layer 515, and a second conductivity-type semiconductor layer 517, a first electrode 520 attached to the first conductivity-type semiconductor layer 513, and a second electrode 530 attached to the second conductivity-type semiconductor layer 517. A conductive substrate 540 may be disposed on a lower surface of the second electrode 530. The conductive substrate 540 may be mounted directly on a circuit substrate, and the like, constituting a light emitting device package.

In a manner similar to the semiconductor light emitting devices 100, 200, 300, and 400 described hereinbefore, the first conductivity-type semiconductor layer 513 may include an n-type nitride semiconductor, and the second conductivity-type semiconductor layer 517 may include a p-type nitride semiconductor. The active layer 515 disposed between the first conductivity-type semiconductor layer 513 and the second conductivity-type semiconductor layer 517 may have an MQW structure in which nitride semiconductor layers having different compositions are laminated in an alternating manner. Optionally, the active layer 515 may also have an SQW structure.

The first electrode 520 may be disposed on a top surface of the first conductivity-type semiconductor layer 513, and the second electrode 530 may be disposed on a lower surface of the second conductivity-type semiconductor layer 517. Light generated by electron-hole recombination in the active layer 515 of the semiconductor light emitting device 500 may be emitted through the top surface of the first conductivity-type semiconductor layer 513. Accordingly, the second electrode 530 may include a material having relatively high reflectivity in order to allow the light generated in the active layer 515 to be reflected in a direction of the top surface of the first conductivity-type semiconductor layer 513.

In particular, a first layer 533 of the second electrode 530 directly bonded to the second conductivity-type semiconductor layer 517 may have relatively high reflectivity. The first layer 533 may include at least one of Ag, Al, Ni, Cr, Cu, Au, Pd, Pt, Sn, Ti, W, Rh, Ir, Ru, Mg, Zn, and an alloy thereof.

A second layer 535 may be formed of a material having a sheet resistance level higher than that of the first layer 533. In a case in which the first layer 533 includes Ag, the second layer 535 may include at least one of Cr, Ti, W, TiW, ITO, ZnO, and Pt. By forming the second layer 535 of a material having a sheet resistance level higher than that of the first layer 533, interface resistance occurring at an interface between the first layer 533 and the second layer 535 may be increased, and thereby currents may spread widely at the interface between the first layer 533 and the second layer 535.

A thickness and an area of the second layer 535 may be determined in various manners, and in the exemplary embodiment, the thickness of the second layer 535 may be less than a half of a thickness of the first layer 533, or less than 1,000 Å. In a case in which the thickness of the second layer 535 is excessively great, a level of resistance on a transfer path of currents applied from the conductive substrate 540 may be increased, and thereby an amount of power consumed in the semiconductor light emitting device 500 may be increased. An area of the second layer 535 may be substantially equal to or smaller than that of the first layer 533.

Referring to FIG. 9, a semiconductor light emitting device 600 according to an exemplary embodiment is illustrated. The semiconductor light emitting device 600 may include nano-light emitting structures 610. In this example, it is illustrated that the nano-light emitting structures 610 have a core-shell structure as a rod structure, but the present disclosure is not limited thereto and the nano-light emitting structures 610 may have a different structure such as a pyramid structure.

The semiconductor light emitting device 600 may include a base layer 650 formed on the substrate 640. The base layer 650 may be a layer providing a growth surface for the nano-light emitting structures 610, which may be a first conductivity-type semiconductor layer. A mask layer 655 having an open area for the growth of the nano-light emitting structures 610 (in particular, the core) may be formed on the base layer 650. The mask layer 655 may be made of a dielectric material such as SiO₂ or SiNx.

In the nano-light emitting structures 610, a first conductivity-type nano-core 613 may be formed by selectively growing a first conductivity-type semiconductor by using the mask layer 655 having an open area. An active layer 615 and a second conductivity-type semiconductor layer 617 may be formed as shell layers on a surface of the nano core 613. Accordingly, the nano-light emitting structures 610 may have a core-shell structure in which the first conductivity-type semiconductor is the nano core 613 and the active layer 615 and the second conductivity-type semiconductor layer 617 enclosing the nano core are shell layers.

The semiconductor light emitting device 600 according to an embodiment of the present disclosure may include a filler material 670 filling spaces between the nano-light emitting structures 610. The filler material 670 may structurally stabilize the nano-light emitting structures 610 and may be employed as necessary in order to optically improve the nano-light emitting structures 610. The filler material 670 may be made of a transparent material such as SiO₂, or the like, but the present disclosure is not limited thereto. An ohmic-contact layer 660 may be formed on the nano-light emitting structures 610 and connected to the second conductivity-type semiconductor layer 617. The semiconductor light emitting device 600 may include first and second electrodes 620 and 630 connected to the base layer 650 formed of the first conductivity-type semiconductor and the ohmic-contact layer 660, respectively.

The second electrode 630 may include a first layer 633 and a second layer 635. The second layer 635 may be formed of a material having a sheet resistance level higher than that of the first layer 633. In a case in which the first layer 633 includes Ag, the second layer 635 may include at least one of Cr, Ti, W, TiW, ITO, ZnO, and Pt. By forming the second layer 635 of a material having a sheet resistance level higher than that of the first layer 633, interface resistance occurring at an interface between the first layer 633 and the second layer 635 may be increased, and thereby currents may spread widely at the interface between the first layer 633 and the second layer 635.

By forming the nano-light emitting structures 610 such that they have different diameters, components, and doping densities, light having two or more different wavelengths may be emitted from the single device. By appropriately adjusting light having different wavelengths, white light may be implemented without using phosphors in the single device. Light having various desired colors or white light having different color temperatures may be implemented by combining a different LED chip with the foregoing device or combining wavelength conversion materials such as phosphors.

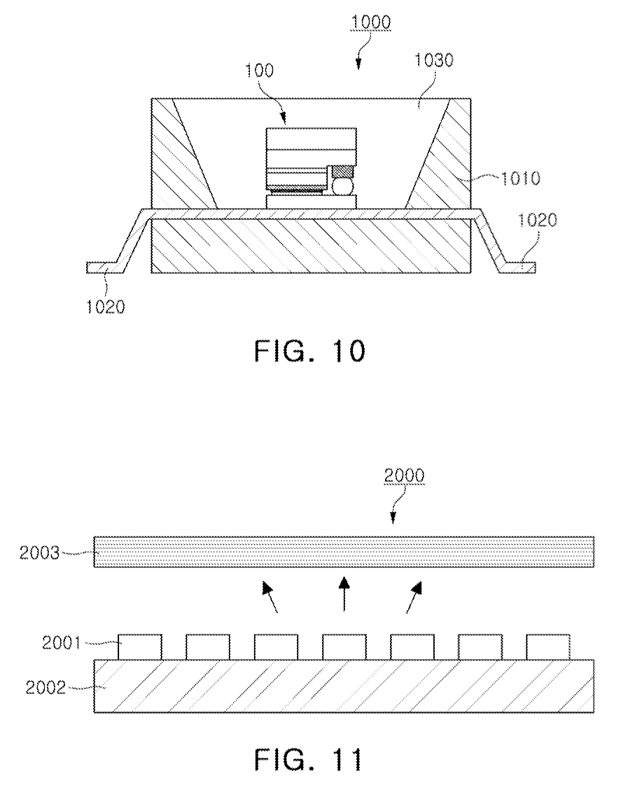

FIG. 10 is a cross-sectional view illustrating a light emitting device package including a semiconductor light emitting device according to an exemplary embodiment in the present disclosure.

A light emitting device package 1000 illustrated in FIG. 10 may include the semiconductor light emitting device 100 illustrated in FIG. 1, a package main body 1010, and a lead frame 1020.

The semiconductor light emitting device 100 may be mounted on the lead frame 1020. First and second electrodes connected to the first and second conductivity-type semiconductor layers of the semiconductor light emitting device 100, respectively, may be electrically connected to the lead frame 1020. As necessary, the semiconductor light emitting device 100 may be mounted on a different area, for example, the package main body 1010, rather than the lead frame 1020. Also, the package main body 1010 may have a cup form in order to enhance light reflectivity efficiency. Such a reflective cup may be formed with an encapsulating portion 1030 therein formed of a light transmissive material in order to encapsulate the semiconductor light emitting device 100. Optionally, the encapsulating portion 1030 may include a predetermined phosphor material, a wavelength converting material, or the like.

Aside from the semiconductor light emitting device 100 illustrated in FIG. 1, the light emitting device package 1000 according to the exemplary embodiment may use semiconductor light emitting devices having a variety of different structures. The semiconductor light emitting devices 200, 300, 400, 500, and 600 illustrated in FIGS. 5 through 9 may be used in the light emitting device package 1000 illustrated in FIG. 10. Here, the light emitting device package 1000 may include at least one wire based on the structure of the semiconductor light emitting devices 200, 300, 400, 500, 600.

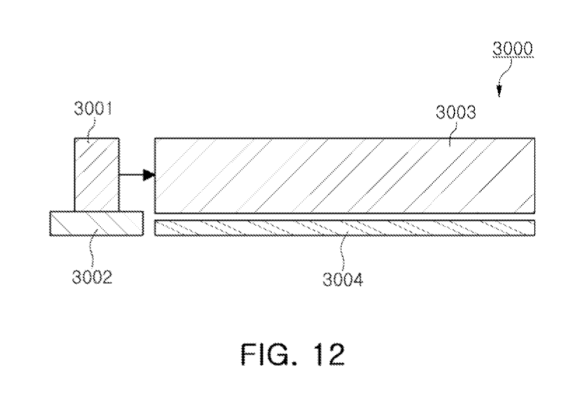

FIGS. 11 and 12 are cross-sectional views illustrating examples of backlight units using semiconductor light emitting devices according to exemplary embodiments in the present disclosure.

Referring to FIG. 11, a backlight unit 2000 may be provided with light sources 2001 mounted on a substrate 2002, and at least one optical sheet 2003 disposed above the light sources 2001. The light sources 2001 may use the aforementioned semiconductor light emitting device or the package including the same.

In a manner dissimilar to that of the backlight unit 2000 illustrated in FIG. 11 in which the light sources 2001 emit light towards an upper portion of the backlight unit 2000 in which a liquid crystal display (LCD) is disposed, a backlight unit 3000 according to a different example illustrated in FIG. 12 may have a light source 3001 mounted on a substrate 3002 and emitting light in a lateral direction, and the emitted light may enter a light guide panel 3003 to be converted to a form of a surface light source. The light passing through the light guide panel 3003 may be dissipated in an upward direction of the backlight unit 3000, and a reflective layer 3004 may be disposed below the light guide panel 3003 in order to enhance light extraction efficiency.

FIG. 13 is an exploded perspective view illustrating an example of a lighting apparatus using a semiconductor light emitting device according to an exemplary embodiment in the present disclosure.

A lighting apparatus 4000 illustrated in FIG. 13 may be provided as a bulb-type lamp byway of example, and may include a light emitting module 4003, a driving unit 4008, and an external connection unit 4010.

Also, the lighting apparatus 4000 may further include external structures such as external and internal housings 4006 and 4009, and a cover unit 4007. The light emitting module 4003 may include a light source 4001 including the aforementioned semiconductor light emitting device or the package including the same, and a circuit substrate 4002 on which the light source 4001 is mounted. For example, the first and second electrodes of the semiconductor light emitting device may be electrically connected to an electrode pattern of the circuit substrate 4002. Although a single light source 4001 is mounted on the circuit substrate 4002 in the exemplary embodiment, the light source 4001 may include a plurality of light sources, as necessary.

The external housing 4006 may serve as a heat dissipation unit, and may include a heat dissipation plate 4004 in direct contact with the light emitting module 4003 to enhance heat dissipation effect, and heat dissipation fins 4005 surrounding a lateral surface of the lighting apparatus 4000. The cover unit 4007 may be mounted on the light emitting module 4003, and may have a convex lens shape. The driving unit 4008 may be installed in the internal housing 4009, and may be connected to the external connection unit 4010 such as a socket structure to be supplied with power externally.

Also, the driving unit 4008 may serve to convert power into an appropriate current source for driving the semiconductor light emitting device, that is, the light source 4001, of the light emitting module 4003, and may provide the converted current source. For example, the driving unit 4008 may be configured of an alternating current-direct current (AC-DC) converter, or a rectifier circuit component.

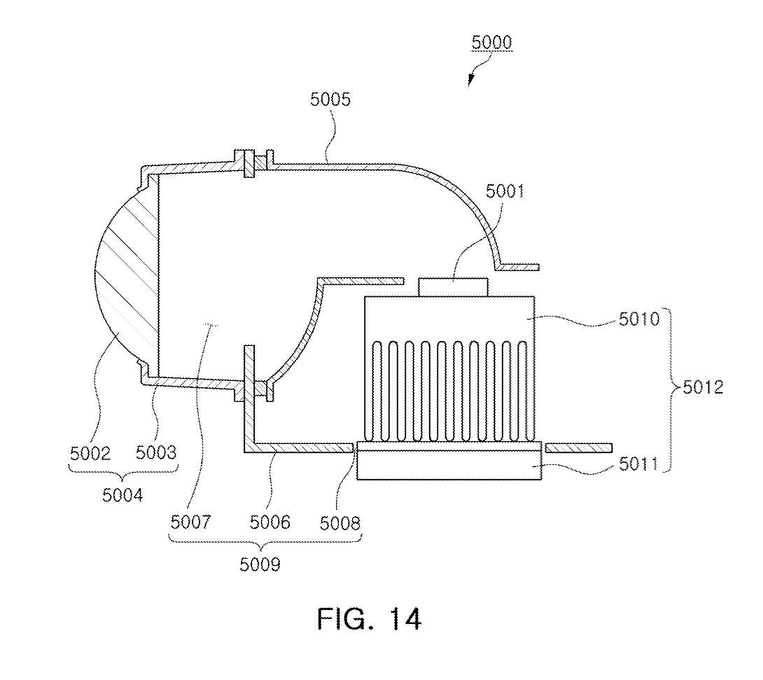

FIG. 14 is a view illustrating an example of a headlamp using a semiconductor light emitting device according to an exemplary embodiment in the present disclosure.

Referring to FIG. 14, a headlamp 5000 to be employed as a vehicle light, or the like, may include a light source unit 5001, a reflection unit 5005, and a lens cover unit 5004. The lens cover unit 5004 may include a hollow guide part 5003 and a lens 5002. The light source unit 5001 may include the aforementioned semiconductor light emitting device or the package including the same.

The headlamp 5000 may further include a heat dissipation unit 5012 externally dissipating heat generated in the light source unit 5001. The heat dissipation unit 5012 may include a heat sink 5010 and a cooling fan 5011 to effectively dissipate heat. Also, the headlamp 5000 may further include a housing 5009 for allowing the heat dissipation unit 5012 and the reflection unit 5005 to be fixed thereto and supported thereby. The housing 5009 may include a center hole 5008 formed in one surface thereof, to which the heat dissipation unit 5012 is coupled and mounted thereon.

Additionally, the housing 5009 may include a forwardly open hole 5007 formed in one surface thereof integrally connected to the other surface thereof and bent in a direction perpendicular thereto. The reflection unit 5005 may be fixed to the housing 5009, such that light generated in the light source unit 5001 may be reflected by the reflection unit 5005, may pass through the forwardly open hole 5007, and may be dissipated externally.

As set forth above, according to exemplary embodiments in the present disclosure, in the semiconductor light emitting device, one or more electrodes may include a plurality of layers having different levels of sheet resistance, and among the plurality of layers, a layer having a relatively high sheet resistance may be disposed on a layer having a relatively low sheet resistance. Accordingly, currents may spread in a direction parallel to an active layer within the electrode, and thus a light emitting area of the active layer may be increased, and thereby luminance of the semiconductor light emitting device may be enhanced.

Various advantages and effects in exemplary embodiments in the present disclosure are not limited to the above-described descriptions and may be easily understood through explanations of concrete embodiments in the present disclosure.

While exemplary embodiments have been shown and described above, it will be apparent to those skilled in the art that modifications and variations could be made without departing from the scope of the present invention as defined by the appended claims.

1. A semiconductor light emitting device, the device comprising:
a light emitting structure including a first conductivity-type semiconductor layer, a second conductivity-type semiconductor layer, and an active layer disposed therebetween;
a first electrode disposed on the light emitting structure to be electrically connected to the first conductivity-type semiconductor layer; and
a second electrode disposed on the light emitting structure to be electrically connected to the second conductivity-type semiconductor layer,
wherein the second electrode includes a first layer disposed on the second conductivity-type semiconductor layer, and a second layer disposed on the first layer, having a sheet resistance higher than that of the first layer, and having a thickness less than that of the first layer, and
a resistivity of a material included in the second layer is greater than a resistivity of a material included in the first layer.

2. The device of claim 1, wherein the second layer has an area smaller than that of the first layer.

3. The device of claim 1, wherein currents applied to the light emitting structure through the first electrode and the second electrode flow at an interface between the first layer and the second layer in a direction parallel to the interface between the first layer and the second layer.

4. The device of claim 1, wherein the first layer is a reflective electrode in ohmic contact with the second conductivity-type semiconductor layer.

5. The device of claim 1, wherein the first layer includes silver (Ag).

6. The device of claim 5, wherein the second layer includes at least one of chromium (Cr), indium tin oxide (ITO), titanium (Ti), tungsten (W), titanium-tungsten —(TiW), platinum (Pt), and zinc oxide (ZnO).

7. The device of claim 1, wherein the thickness of the second layer is less than a half of a thickness of the first layer.

8. The device of claim 1, wherein the thickness of the second layer is less than 1,000 angstrom (Å).

9. The device of claim 1, wherein the first electrode is electrically connected to the first conductivity-type semiconductor layer through at least one contact hole.

10. The device of claim 1, wherein the first conductivity-type semiconductor layer includes a plurality of nanocores, and the active layer and the second conductivity-type semiconductor layer are sequentially disposed on the plurality of nanocores.

11. The device of claim 1, wherein the second electrode includes a third layer disposed on the second layer and including an Ag-palladium (Pd)-copper (Cu) alloy.

12. A semiconductor light emitting device, the device comprising:
a light emitting structure including a first conductivity-type semiconductor layer, an active layer, and a second conductivity-type semiconductor layer sequentially laminated therein;
a first electrode disposed on the light emitting structure to be electrically connected to the first conductivity-type semiconductor layer; and
a second electrode disposed on the light emitting structure to be electrically connected to the second conductivity-type semiconductor layer,
wherein the second electrode includes a first layer disposed on the second conductivity-type semiconductor layer, and a second layer disposed on the first layer, having an area smaller than that of the first layer, and having a sheet resistance higher than that of the first layer, and
a resistivity of a material included in the second layer is greater than a resistivity of a material included in the first layer.

13. The device of claim 12, wherein the second layer has a thickness less than that of the first layer.

14. The device of claim 13, wherein the thickness of the second layer is a half of a thickness of the first layer.

15. The device of claim 12, wherein currents applied to the light emitting structure through the first electrode and the second electrode flow at an interface between the first layer and the second layer in a direction parallel to the interface between the first layer and the second layer.

16. A semiconductor light emitting device, the device comprising:
a light emitting structure including a first conductivity-type semiconductor layer, a second conductivity-type semiconductor layer, and an active layer disposed therebetween;
a first electrode electrically connected to the first conductivity-type semiconductor layer; and
a second electrode including first and second layers and electrically connected to the second conductivity-type semiconductor layer,
wherein the first layer of the second electrode is interposed between the second layer of the second electrode and the second conductivity-type semiconductor layer, and a sheet resistance of the second layer is greater than that of the first layer, and
a resistivity of a material included in the second layer is greater than a resistivity of a material included in the first layer.

17. The device of claim 16, wherein a thickness of the second layer is less than a thickness of the first layer.

18. The device of claim 17, wherein the thickness of the second layer is less than a half of the thickness of the first layer.

19. The device of claim 17, wherein the thickness of the second layer is less than 1,000 angstrom (Å).

20. The device of claim 16, wherein the second layer has an area less than that of the first layer.
